(19) United States
(12) Patent Application Publication
(10) Pub. No.: US 2024/0055053 A1
(43) Pub. Date: Feb. 15, 2024

(54) PROGRAMMING METHOD OF NON-VOLATILE MEMORY CELL

(71) Applicant: eMemory Technology Inc., Hsin-Chu (TW)

(72) Inventors: Chia-Jung HSU, Hsinchu County (TW); Chun-Yuan LO, Hsinchu County (TW); Chun-Hsiao LI, Hsinchu County (TW); Chang-Chun LUNG, Hsinchu County (TW)

(21) Appl. No.: 18/227,409

(22) Filed: Jul. 28, 2023

Related U.S. Application Data
(60) Provisional application No. 63/397,394, filed on Aug. 12, 2022.

(51) Int. Cl. G11C 16/10; G11C 16/32; G11C 16/34

(52) U.S. Cl. CPC G11C 16/102; G11C 16/32; G11C 16/3459

(57) ABSTRACT

A programming method of a non-volatile memory cell is provided. The non-volatile memory cell includes a memory transistor. Firstly, a current limiter is provided, and the current limiter is connected between a drain terminal of the memory transistor and a ground terminal. Then, a program voltage is provided to a source terminal of the memory transistor, and a control signal is provided to a gate terminal of the memory transistor. In a first time period of a program action, the control signal is gradually decreased from a first voltage value, so that the memory transistor is firstly turned off and then slightly turned on. When the memory transistor is turned on, plural hot electrons are injected into a charge trapping layer of the memory transistor.

This application claims the benefit of U.S. provisional application Ser. No. 63/397,394, filed Aug. 12, 2022, the subject matters of which are incorporated herein by references.

### FIELD OF THE INVENTION

The present invention relates to a programming method of a non-volatile memory, and more particularly to a programming method of a non-volatile memory cell with P-type transistors.

### BACKGROUND OF THE INVENTION

Generally, a memory cell of a non-volatile memory comprises a storage unit. For example, the storage unit is a memory transistor. According to the number of charges in the charge trapping layer of the memory transistor, a storage state of the memory cell is determined.

FIG. 1A is a schematic circuit diagram of a non-volatile memory cell. As shown in FIG. 1A, the non-volatile memory cell 100 comprises a select transistor M_{S} and a memory transistor M_{F}. The select transistor M_{S} and the memory transistor M_{F} are P-type transistors. In case that no electrons are stored in the charge trapping layer of the memory transistor M_{F}, the non-volatile memory cell 100 is in a first storage state. Whereas, in case that electrons are stored in the charge trapping layer of the memory transistor M_{F}, the non-volatile memory cell 100 is in a second storage state.

The source terminal of the select transistor M_{S} is connected with a source line SL. The drain terminal of the select transistor M_{S} is connected with a node a. The gate terminal of the select transistor M_{S} is connected with a word line WL. The source terminal of the memory transistor M_{F} is connected with the node a. The drain terminal of the memory transistor M_{F} is connected with a bit line BL. The gate terminal of the memory transistor M_{F} is connected with a control line CL.

During a program cycle, a program action of the non-volatile memory cell 100 is performed. Meanwhile, the word line WL receives an on voltage V_{ON}, the source line SL receives a program voltage V_{PP}, the bit line BL receives a ground voltage (0V), and the control line CL receives a control signal S_{CL}.

Since the word line WL receives the on voltage V_{ON}, the select transistor MS is fully turned on. Consequently, the program voltage V_{PP} received by the source line SL is transmitted to the node a. That is, when the program action is performed, the voltage at the node a is nearly equal to the program voltage V_{PP}. Meanwhile, according to the control signal S_{CL}, the hot electrons are injected into the charge trapping layer of the memory transistor M_{F}. Consequently, the storage state of the non-volatile memory cell 100 is changed from the first storage state to the second storage state.

FIGS. 1B, 1C and 1D are plots illustrating associated signals of the memory transistor of FIG. 1A when a program action is performed in response to a fixed control signal S_{CL}. For example, the program voltage V_{PP} received by the source line SL is 6V, the on voltage V_{ON} received by the word line WL is 0V, the bit line BL receives the ground voltage (0V), and the control signal S_{CL} is 5.5V. That is, the gate-source voltage V_{GS} of the memory transistor M_{F} may be calculated according to the formula: S_{CL}−V_{PP}=5.5V−6V=−0.5V. Under this circumstance, the threshold voltage Vt of the memory transistor M_{F} is slightly higher than the gate-source voltage V_{GS} of the memory transistor M_{F}. Consequently, the memory transistor M_{F} is slightly turned on. For example, in the first storage state, no electrons are stored in the charge trapping layer of the memory transistor M_{F}, and the threshold voltage Vt of the memory transistor M_{F} is −0.4V.

Please refer to FIG. 1B. In an early stage of the program action, the memory transistor M_{F} is slightly turned on, and a channel current I_{CH} of the memory transistor M_{F} is about 10 μA. Under this circumstance, a gate current I_{G} corresponding to the hot electrons is larger. The flowing direction of the gate current I_{G} and the injecting direction of the hot electrons are opposite. Meanwhile, since a channel hot hole induced hot electron injection (CHHIHEI) effect is generated, a greater number of hot electrons are injected into the charge trapping layer of the memory transistor M_{F}. As the number of the hot electrons injected into the charge trapping layer is increased, the threshold voltage Vt of the memory transistor M_{F} is correspondingly increased.

Please refer to FIG. 10. In the middle stage of the program action, electrons are injected into the charge trapping layer of the memory transistor M_{F}. Consequently, the threshold voltage Vt of the memory transistor M_{F} is increased. The control signal S_{CL} is not changed. That is, the gate-source voltage V_{GS} of the memory transistor M_{F} is not changed. Since the difference between the threshold voltage Vt of the memory transistor M_{F} and the gate-source voltage V_{GS} of the memory transistor M_{F} is expanded, the memory transistor M_{F} is further turned on. Under this circumstance, the channel current I_{CH} of the memory transistor M_{F} is increased to about 150 μA. However, in this situation, the magnitude of the gate current I_{G} is decreased. That is, the number of hot electrons injected into the charge trapping layer of the memory transistor M_{F} is decreased.

Please refer to FIG. 1D. In the later stage of the program action, the threshold voltage Vt of the memory transistor M_{F} is gradually continuously increased. Consequently, the difference between the threshold voltage Vth of the memory transistor M_{F} and the gate-source voltage V_{GS} of the memory transistor M_{F} is continuously expanded. Meanwhile, the memory transistor M_{F} is fully turned on. Under this circumstance, the channel current I_{CH} of the memory transistor M_{F} is increased to about 200 μA. Meanwhile, since a channel hot hole injection effect (CHHI) effect is generated, hot holes are injected into the charge trapping layer of the memory transistor M_{F}, and the magnitude of the gate current I_{G} is gradually increased. However, since hot holes are injected into the charge trapping layer of the memory transistor M_{F}, the reliability of the non-volatile memory cell 100 is deteriorated.

As mentioned in FIGS. 1A to 1D, the memory transistor M_{F} of the non-volatile memory cell 100 is slightly turned on in the early stage of the program action only. Meanwhile, the gate current I_{G} is larger. That is, more hot electrons are injected into the charge trapping layer of the memory transistor M_{F}.

After the middle stage of the program action, the threshold voltage Vt of the memory transistor M_{F} is increased. Meanwhile, the channel voltage I_{CH} of the memory transistor M_{F} is increased. However, the magnitude of the gate current I_{G} is decreased. The decreased gate current I_{G} indicates that a smaller number of hot electrons are injected into the charge trapping layer. In other words, the increased channel current I_{CH} cannot enhance the program efficiency but increase the power consumption of the program action. Under this circumstance, the reliability of the non-volatile memory cell 100 is deteriorated.

Moreover, if the number of hot electrons injected into the charge trapping layer is not sufficient in the early stage of the program action, the non-volatile memory cell is insufficiently programmed. Under this circumstance, the second storage state of the non-volatile memory cell cannot be normally judged.

### SUMMARY OF THE INVENTION

An embodiment of the present invention provides a programming method of a non-volatile memory cell. The non-volatile memory cell includes a memory transistor. The method includes steps of: limiting a channel current of the memory transistor lower than or equal to a limited current; and providing a program voltage to a source terminal of the memory transistor, and providing a control signal to a gate terminal of the memory transistor. During a program cycle, a program action is performed, and the program cycle contains plural time periods. In a first time period of the plural time periods, the control signal is gradually decreased from a first voltage value, so that the memory transistor is firstly turned off and then turned on. When the memory transistor is turned on, plural hot electrons are injected into the memory transistor. In a second time period of the plural time periods after the first time period, the control signal is gradually decreased from a second voltage value, so that the memory transistor is firstly turned off and then turned on. When the memory transistor is turned on, the plural hot electrons are injected into the memory transistor. The second voltage value is equal to the first voltage value plus a first voltage increment.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram of a non-volatile memory cell;

FIGS. 1B, 10 and 1D (prior art) are plots illustrating associated signals of the memory transistor of FIG. 1A when a program action is performed in response to a fixed control signal;

FIG. 2A is a schematic circuit diagram of a non-volatile memory cell;

FIG. 2B is a schematic timing diagram illustrating a waveform of a ramped-up control signal when a program action is performed according to a first embodiment of the present invention;

FIGS. 2C, 2D, 2E, 2F and 2G are plots illustrating associated signals of the memory transistor of FIG. 2A when the program action is performed in response to the ramped-up control signal;

FIG. 3A is a schematic circuit diagram of a non-volatile memory cell;

FIG. 3B is a schematic timing diagram illustrating a waveform of a ramped-up control signal when a program action is performed according to a second embodiment of the present invention;

FIG. 3C is a schematic timing diagram illustrating the change of a gate-source voltage V_{GS} of the memory transistor M_{F} in the non-volatile memory cell according to the second embodiment of the present invention;

FIG. 3D is a schematic timing diagram illustrating the change of a source-drain voltage V_{SD} of the memory transistor M_{F} in the non-volatile memory cell according to the second embodiment of the present invention;

FIG. 4A is a schematic circuit diagram of a non-volatile memory cell;

FIG. 4B is a schematic timing diagram illustrating a waveform of a control signal when a program action is performed according to a third embodiment of the present invention;

FIG. 4C is a schematic timing diagram illustrating the change of a gate-source voltage V_{GS} of the memory transistor M_{F} in the non-volatile memory cell according to the third embodiment of the present invention;

FIG. 4D is a schematic timing diagram illustrating the change of a source-drain voltage V_{SD} of the memory transistor M_{F} in the non-volatile memory cell according to the third embodiment of the present invention;

FIG. 5 shows another example of the schematic timing diagram illustrating a waveform of a control signal when a program action is performed on the non-volatile memory cell;

FIG. 6A is a schematic timing diagram illustrating a waveform of a control signal when a program action and a verification action are performed; and

FIGS. 6B and 6C are schematic timing diagrams illustrating two variant examples of decreasing the control signal in a time period.

### DETAILED DESCRIPTION OF PREFERRED EMBODIMENTS

In order to inject sufficient number of hot electrons into the memory transistor during the program action, the present invention provides a programming method of a non-volatile memory cell. Hereinafter, some embodiments of the programming method will be described. In some embodiments, the memory transistor can be a charge-trapping type memory transistor, for example, a Silicon-Oxide-Nitride-Oxide-Silicon (SONOS) transistor.

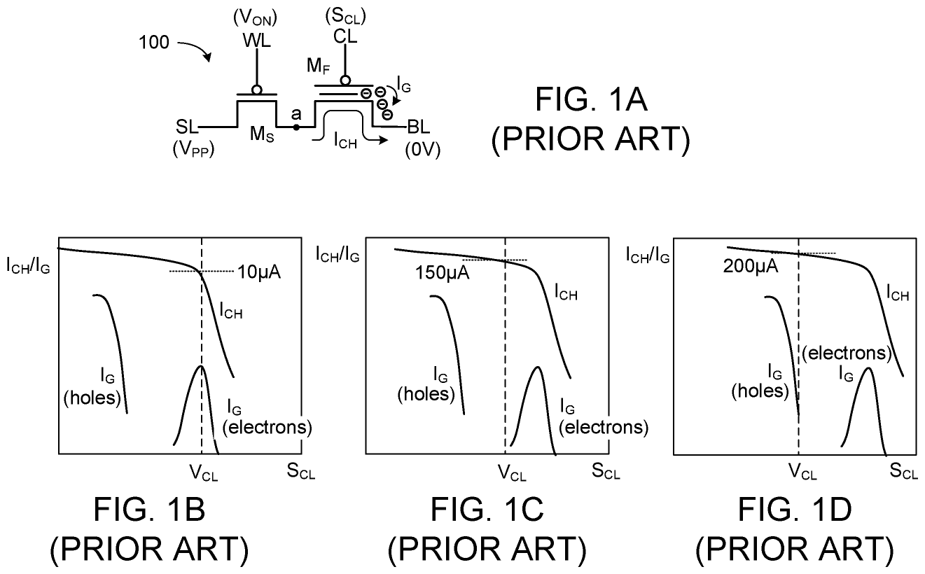

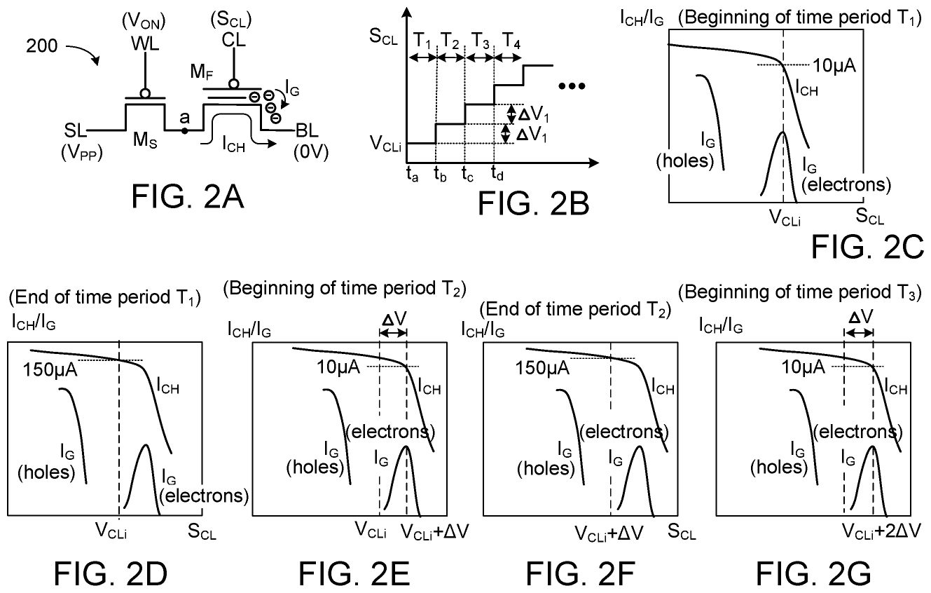

Please refer to FIGS. 2A to 2G. FIG. 2A is a schematic circuit diagram of a non-volatile memory cell. FIG. 2B is a schematic timing diagram illustrating a waveform of a ramped-up control signal S_{CL} when a program action is performed according to a first embodiment of the present invention. FIGS. 2C, 2D, 2E, 2F and 2G are plots illustrating associated signals of the memory transistor of FIG. 2A when the program action is performed in response to the ramped-up control signal S_{CL}. During a program cycle, a program action of the non-volatile memory cell 200 is performed. In this embodiment, the program cycle contains plural time period. The circuitry structure of the non-volatile memory cell 200 as shown in FIG. 2A is similar to that of the non-volatile memory cell as shown in FIG. 1A, and not redundantly described herein.

As shown in FIG. 2B, the program action is started after the time point ta. In the time period T₁ between the time point ta and the time point t_{b}, the control signal S_{CL} is a pulse with 100% duty cycle. The pulse height is equal to an initial voltage V_{CLi}. That is, in the time period T₁, the control signal S_{CL} is equal to the initial voltage V_{CLi}.

In the time period T₂ between the time point t_{b} and the time point t_{c}, the control signal S_{CL} is a pulse with 100% duty cycle. The pulse height is equal to the initial voltage V_{CLi} plus a voltage increment ΔV₁. That is, in the time period T₂, the control signal S_{CL} is equal to V_{CLi} ΔV₁. The voltage increment ΔV₁ is greater than zero.

In the time period T₃ between the time point t_{c} and the time point t_{d}, the control signal S_{CL} is a pulse with 100% duty cycle. The pulse height is equal to the initial voltage V_{CLi} plus two times the voltage increment ΔV₁. That is, in the time period T₃, the control signal S_{CL} is equal to V_{CLi}+2ΔV₁.

The rest may be deduced by analogy. That is, in the other time periods of the program cycle, the control signal S_{CL} is ramped up.

When a program action of the non-volatile memory cell 200 is performed, the word line WL receives an on voltage V_{ON}, the source line SL receives a program voltage V_{PP}, the bit line BL receives a ground voltage (0V), and the control line CL receives a control signal S_{CL}. Since the word line WL receives the on voltage V_{ON}, the select transistor M_{S} is fully turned on. Consequently, the program voltage V_{PP} received by the source line SL is transmitted to the node a. That is, when the program action is performed, the voltage at the source terminal of the memory transistor M_{F} is nearly equal to the program voltage V_{PP}. Meanwhile, according to the ramped-up control signal S_{CL}, the hot electrons are injected into the charge trapping layer of the memory transistor M_{F}. Consequently, the storage state of the non-volatile memory cell 200 is changed from the first storage state to the second storage state.

For example, the program voltage V_{PP} received by the source line SL is 6V, the on voltage V_{ON} received by the word line WL is 0V, and the ground voltage received by the bit line BL is 0V. In addition, the initial voltage V_{CLi} is 5.5V, and the voltage increment ΔV₁ is 0.2V.

In the time period T₁ of the program action, the gate-source voltage V_{GS} of the memory transistor M_{F} may be calculated according to the formula: V_{CLi}−V_{PP}=5.5V−6V=−0.5V. Under this circumstance, the threshold voltage Vt of the memory transistor M_{F} is slightly higher than the gate-source voltage V_{GS} of the memory transistor M_{F}. Consequently, the memory transistor M_{F} is slightly turned on. For example, in the first storage state, no electrons are stored in the charge trapping layer of the memory transistor M_{F}, and the threshold voltage Vt of the memory transistor M_{F} is −0.4V.

Please refer to FIG. 2C. In the beginning of the time period T₁ (i.e., after the time point tₐ), the memory transistor M_{F} is slightly turned on, and a channel current I_{CH} of the memory transistor M_{F} is about 10 μA. Meanwhile, since a channel hot hole induced hot electron injection (CHHIHEI) effect is generated, a gate current I_{G} corresponding to the hot electrons is larger. Consequently, a greater number of hot electrons are injected into the charge trapping layer of the memory transistor M_{F}. As the number of the hot electrons is increased, the threshold voltage Vt of the memory transistor M_{F} is correspondingly increased.

Please refer to FIG. 2D. At the end of the time period T₁ (i.e., before the time point t_{b}), the threshold voltage Vt of the memory transistor M_{F} is increased. Since the difference between the threshold voltage Vt of the memory transistor M_{F} and the gate-source voltage V_{GS} of the memory transistor M_{F} is expanded, the memory transistor M_{F} is further turned on. Under this circumstance, the channel current I_{CH} of the memory transistor M_{F} is increased to about 150 μA. However, in this situation, the magnitude of the gate current I_{G} is decreased. That is, the number of hot electrons injected into the charge trapping layer of the memory transistor M_{F} is decreased.

Please refer to FIG. 2E. In the beginning of the time period T₂ (i.e., after the time point t_{b}), the control signal S_{CL} is increased to (V_{CLi}+ΔV₁), and the gate-source voltage V_{GS} of the memory transistor M_{F} is increased. Under this circumstance, the threshold voltage Vt of the memory transistor M_{F} is slightly higher than the gate-source voltage V_{GS} of the memory transistor M_{F}. Consequently, the memory transistor M_{F} is slightly turned on. Under this circumstance, the channel current I_{CH} of the memory transistor M_{F} is decreased to about 10 μA. Meanwhile, since the CHHIHEI effect is generated, a gate current I_{G} corresponding to the hot electrons is larger. Consequently, a greater number of hot electrons are injected into the charge trapping layer of the memory transistor M_{F}. As the number of the hot electrons is increased, the threshold voltage Vt of the memory transistor M_{F} is correspondingly increased.

Please refer to FIG. 2F. At the end of the time period T₂ (i.e., before the time point t_{c}), the threshold voltage Vt of the memory transistor M_{F} is increased. Since the difference between the threshold voltage Vt of the memory transistor M_{F} and the gate-source voltage V_{GS} of the memory transistor M_{F} is expanded, the memory transistor M_{F} is further turned on. Under this circumstance, the channel current I_{CH} of the memory transistor M_{F} is increased to about 150 μA. However, in this situation, the magnitude of the gate current I_{G} is decreased. That is, the number of hot electrons injected into the charge trapping layer of the memory transistor M_{F} is decreased.

Please refer to FIG. 2G. Similarly, in the beginning of the time period T₃ (i.e., after the time point t_{c}), the control signal S_{CL} is (V_{CLi}+2ΔV₁), and the gate-source voltage V_{GS} of the memory transistor M_{F} is increased. Under this circumstance, the threshold voltage Vt of the memory transistor M_{F} is slightly higher than the gate-source voltage V_{GS} of the memory transistor M_{F}. Consequently, the memory transistor M_{F} is slightly turned on. Under this circumstance, the channel current I_{CH} of the memory transistor M_{F} is decreased to about 10 μA. Meanwhile, since the CHHIHEI effect is generated, a greater number of hot electrons are injected into the charge trapping layer of the memory transistor M_{F}. As the number of the hot electrons is increased, the threshold voltage Vt of the memory transistor M_{F} is correspondingly increased.

The rest may be deduced by analogy. In the time period T₄, the control signal S_{CL} is increased to (V_{CLi}+3ΔV₁). During the program action, the memory transistor M_{F} of the non-volatile memory cell 200 is switched between the slightly-turned-on state and the further-turned on state according to the ramped-up control signal S_{CL}. In this way, the CHHIHEI effect can be continuously generated. Consequently, sufficient hot electrons can be injected into the charge trapping layer of the memory transistor M_{F} during the program action.

As can be seen from the above descriptions of FIGS. 2A to 2G, the memory transistor M_{F} is maintained in the on state and the control signal S_{CL} is gradually increased to adjust the turn-on extent of the memory transistor M_{F} when the program action of the non-volatile memory cell 200 is performed. As a consequence, more hot electrons can be injected into the charge trapping layer of the memory transistor M_{F}. However, in the latter part of each time period, the channel current I_{CH} still rises. In other word, the power consumption during the program action is still high.

In order to reduce the power consumption of the non-volatile memory cell 200 during the program action, the above embodiment needs to be modified. For example, in another embodiment, the non-volatile memory cell is further connected with a current limiter, and the program action is controlled according to the control signal S_{CL} of the first embodiment.

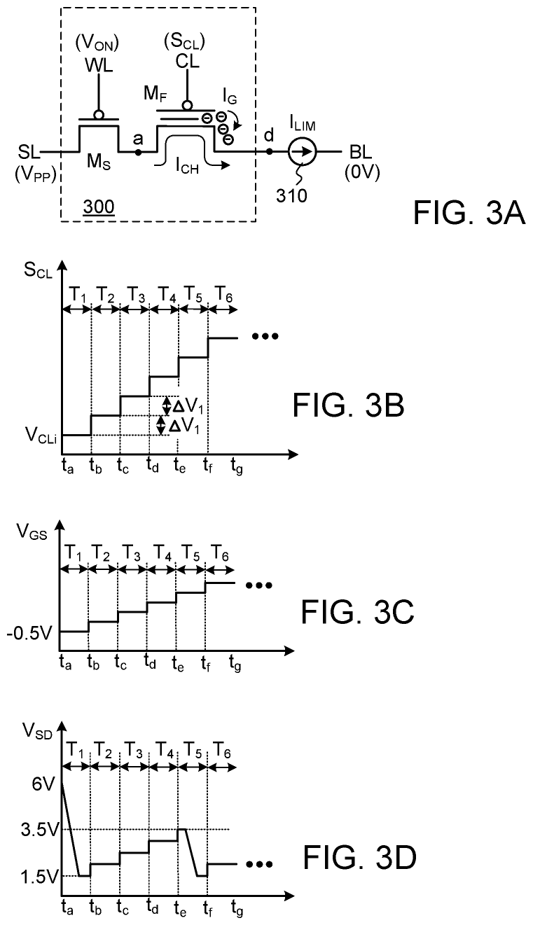

FIG. 3A is a schematic circuit diagram of a non-volatile memory cell. FIG. 3B is a schematic timing diagram illustrating a waveform of a ramped-up control signal S_{CL} when a program action is performed according to a second embodiment of the present invention. In comparison with the non-volatile memory cell 200 shown in FIG. 2A, the non-volatile memory cell 300 of this embodiment is further connected with a current limiter 310. As shown in FIG. 3B, the control signal S_{CL} for controlling the program action is similar to that of FIG. 2B.

In the non-volatile memory cell 300, the source terminal of the select transistor M_{S} is connected with a source line SL. The drain terminal of the select transistor M_{S} is connected with the node a. The gate terminal of the select transistor M_{S} is connected with the word line WL. The source terminal of the memory transistor M_{F} is connected with the node a. The drain terminal of the memory transistor M_{F} is connected with a node d. The gate terminal of the memory transistor M_{F} is connected with a control line CL.

The current limiter 310 is connected between the node d and a bit line BL. The current limiter 310 is a current source for providing a limited current I_{LIM}.

When the program action of the non-volatile memory cell 300 is performed, the current limiter 310 is connected between the drain terminal of the memory transistor M_{F} and the bit line BL. Moreover, the word line WL receives an on voltage V_{ON}, the source line SL receives a program voltage V_{PP}, the bit line BL receives a ground voltage (0V), and the control line CL receives a control signal S_{CL}. For example, the program voltage V_{PP} is 6V, the on voltage V_{ON} is 0V, and the ground voltage is 0V. Moreover, the initial voltage V_{CLi} is 5.5V, the voltage increment ΔV₁ is 0.2V, and the magnitude of the limited current I_{LIM} is 20 μA. In other words, the maximum of the channel current I_{CH} of the memory transistor M_{F} is limited to 20 μA by the current limiter 310, and the magnitude of the channel current I_{CH} is lower than or equal to the limited current I_{LIM}.

As mentioned above, when the program action is performed, the non-volatile memory cell 300 connected with the current limiter 310 is controlled according to the ramped-up control signal S_{CL}. However, the program efficiency of this control method is largely deteriorated. The reason will be described as follows.

FIG. 3C is a schematic timing diagram illustrating the change of a gate-source voltage V_{GS} of the memory transistor M_{F} in the non-volatile memory cell according to the second embodiment of the present invention. FIG. 3D is a schematic timing diagram illustrating the change of a source-drain voltage V_{SD} of the memory transistor M_{F} in the non-volatile memory cell according to the second embodiment of the present invention. For example, in the first storage state, no electrons are stored in the charge trapping layer of the memory transistor M_{F}. Under this circumstance, the threshold voltage Vt is −0.4V.

In the beginning of the time period T₁ (i.e., after the time point tₐ), the gate-source voltage V_{GS} of the memory transistor M_{F} may be calculated according to the formula: V_{CLi}−V_{PP}=5.5V−6V=−0.5V. Under this circumstance, the threshold voltage Vt of the memory transistor M_{F} is slightly higher than the gate-source voltage V_{GS} of the memory transistor M_{F}. Consequently, the memory transistor M_{F} is slightly turned on, and a channel current I_{CH} of the memory transistor M_{F} is about 10 μA. Meanwhile, since the CHHIHEI effect is generated, a gate current I_{G} corresponding to the hot electrons is larger. Consequently, a greater number of hot electrons are injected into the charge trapping layer of the memory transistor M_{F}. As the number of the hot electrons is increased, the threshold voltage Vt of the memory transistor M_{F} is correspondingly increased.

At the end of the time period T₁ (i.e., before the time point t_{b}), the threshold voltage Vt of the memory transistor M_{F} is increased. Since the difference between the threshold voltage Vt of the memory transistor M_{F} and the gate-source voltage V_{GS} of the memory transistor M_{F} is expanded, the memory transistor M_{F} is further turned on. However, since the limited current I_{LIM} is 20 μA, the channel current I_{CH} of the memory transistor M_{F} is maintained at about 20 μA. Under this circumstance, the drain voltage of the memory transistor M_{F} (i.e., the voltage at the node d) is increased to about 4.5V. Meanwhile, the source-drain voltage V_{SD} of the memory transistor M_{F} is 1.5V (i.e., 6V−4.5V=1.5V). Since the source-drain voltage V_{SD} of the memory transistor M_{F} is too low, the CHHIHEI effect cannot be generated.

In the time period T₂ (i.e., the interval between the time point to and the time point tₐ), the control signal S_{CL} is increased by one voltage increment ΔV₁. Consequently, the gate-source voltage V_{GS} of the memory transistor M_{F} is increased. Under this circumstance, the voltage at the node d is decreased to 4.0V, and the source-drain voltage V_{SD} of the memory transistor M_{F} is increased to about 2.0V. Since the source-drain voltage V_{SD} of the memory transistor M_{F} is too low, the CHHIHEI effect cannot be generated.

In the time period T₃ (i.e., in the time interval between the time point t_{c} and the time point t_{d}), the control signal S_{CL} is increased by one additional voltage increment ΔV₁. Consequently, the gate-source voltage V_{GS} of the memory transistor M_{F} is increased. Meanwhile, the voltage at the node d is decreased to 3.5V, and the source-drain voltage V_{SD} of the memory transistor M_{F} is increased to about 2.5V. Since the source-drain voltage V_{SD} of the memory transistor M_{F} is too low, the CHHIHEI effect cannot be generated.

In the time period T₄ (i.e., in the time interval between the time point tₑ and the time point t_{f}), the control signal S_{CL} is increased by one additional voltage increment ΔV₁ again. Consequently, the gate-source voltage V_{GS} of the memory transistor M_{F} is increased. Meanwhile, the voltage at the node d is decreased to 3.0V, and the source-drain voltage V_{SD} of the memory transistor M_{F} is increased to about 3.0V. Since the source-drain voltage V_{SD} of the memory transistor M_{F} is too low, the CHHIHEI effect cannot be generated.

In the beginning of the time period T₅ (i.e., after the time point tₑ), the control signal S_{CL} is increased by one additional voltage increment ΔV₁ again. Consequently, the gate-source voltage V_{GS} of the memory transistor M_{F} is increased. Meanwhile, the voltage at the node d is decreased to 2.5V, and the source-drain voltage V_{SD} of the memory transistor M_{F} is increased to about 3.5V. Since the source-drain voltage V_{SD} is 3.5V, the CHHIHEI effect can be generated. Consequently, hot electrons are injected into the charge trapping layer of the memory transistor M_{F} again.

At the end of the time period T₅ (i.e., before the time point t_{f}), the threshold voltage Vt of the memory transistor M_{F} is increased. Since the difference between the threshold voltage Vt of the memory transistor M_{F} and the gate-source voltage V_{GS} of the memory transistor M_{F} is expanded, the memory transistor M_{F} is further turned on. However, since the limited current I_{LIM} is 20 μA, the channel current I_{CH} of the memory transistor M_{F} is maintained at about 20 μA. Under this circumstance, the drain voltage of the memory transistor M_{F} (i.e., the voltage at the node d) is increased to about 4.5V. Meanwhile, the source-drain voltage V_{SD} of the memory transistor M_{F} is 1.5V (i.e., 6V−4.5V=1.5V). Since the source-drain voltage V_{SD} of the memory transistor M_{F} is too low, the CHHIHEI effect cannot be generated.

Similarly, in the time period T₆ (i.e., in the time interval between the time point t_{f} and the time point t g), the control signal S_{CL} is increased by one additional voltage increment ΔV₁ again. Consequently, the gate-source voltage V_{GS} of the memory transistor M_{F} is increased. Meanwhile, the voltage at the node d is decreased to 4.0V, and the source-drain voltage V_{SD} of the memory transistor M_{F} is increased to about 2.0V. Since the source-drain voltage V_{SD} of the memory transistor M_{F} is too low, the CHHIHEI effect cannot be generated.

The rest may be deduced by analogy. The control signal S_{CL} is gradually continuously increased. For example, the CHHIHEI effect is not generated until a time period T₉ (not shown). In the time period T₉, the CHHIHEI effect is generated. Consequently, hot electrons are injected into the charge trapping layer of the memory transistor M_{F} again.

As mentioned above, the non-volatile memory cell 300 is connected with the current limiter during the program action. In addition, the program action is controlled according to the control signal S_{CL} as shown in FIG. 3B. In this way, the memory transistor M_{F} is continuously turned on. However, since the source-drain voltage V_{SD} of the memory transistor M_{F} is too low, the program efficiency is deteriorated.

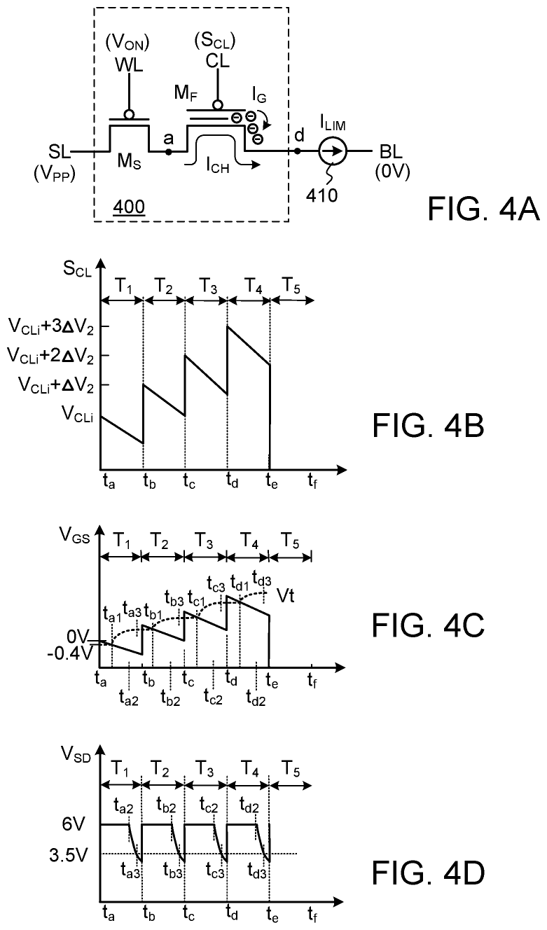

FIG. 4A is a schematic circuit diagram of a non-volatile memory cell. FIG. 4B is a schematic timing diagram illustrating a waveform of a control signal S_{CL} when a program action is performed according to a third embodiment of the present invention. During a program cycle, a program action of the non-volatile memory cell 400 is performed. In this embodiment, the program cycle contains plural time period. The circuitry structure of the non-volatile memory cell 400 of this embodiment is identical to the non-volatile memory cell 300 shown in FIG. 3A. The non-volatile memory cell 400 of this embodiment is connected with a current limiter 410. The connecting relationships between the associated components are not redundantly described herein.

When the program action of the non-volatile memory cell 400 is performed, the current limiter 410 is connected between the drain terminal of the memory transistor M_{F} and the bit line BL. Moreover, the word line WL receives an on voltage V_{ON}, the source line SL receives a program voltage V_{PP}, the bit line BL receives a ground voltage (0V), and the control line CL receives a control signal S_{CL}. Since the word line WL receives the on voltage V_{ON}, the select transistor M_{S} is fully turned on. Consequently, the program voltage V_{PP} received by the source line SL is transmitted to the node a. That is, when the program action is performed, the voltage at the source terminal of the memory transistor M_{F} is nearly equal to the program voltage V_{PP}. That is, when the program action is performed, the voltage at the node a is nearly equal to the program voltage V_{PP}. Meanwhile, according to the control signal S_{CL}, hot electrons are injected into the charge trapping layer of the memory transistor M_{F}. Consequently, the storage state of the non-volatile memory cell 400 is changed from the first storage state to the second storage state.

For example, the program voltage V_{PP} is 6V, and the on voltage V_{ON} is 0V. Moreover, the initial voltage V_{CLi} is 6V, the voltage increment ΔV₂ is 0.5V, and the magnitude of the limited current I_{LIM} is 20 μA. In other words, the maximum of the channel current I_{CH} of the memory transistor M_{F} is limited to 20 μA by the current limiter 410.

In the above-described embodiment, the channel current I_{CH} of the memory transistor M_{F} is limited by the current limiter 410. In another embodiment, the current limiter 410 shown in FIG. 4A may be omitted, and the select transistor M_{S} can be used as the current limiter to limit the channel current I_{CH} of the memory transistor M_{F}. For example, when the program action of the non-volatile memory cell 400 is performed, a higher on voltage V_{ON} may applied to the word line WL to control the select transistor M_{S} not to be completely turned on, thereby limiting the conductivity capability of the select transistor M_{S} to determine a limited current. In this way, the channel current I_{CH} of the memory transistor M_{F} is lower than or equal to a limited current I_{LIM} determined by the on voltage V_{ON}. The on voltage V_{ON} is greater than 0V, e.g. 4V.

In this embodiment, the control signal SCS is adjusted when the program action is performed. Consequently, the non-volatile memory cell 400 is selectively operated in an off state or a slightly-turned-on state. The associated operations will be described in more details as follows.

In this embodiment, the control signal S_{CL} is adjusted during the program action. For example, in each time period of the program action, the control signal S_{CL} is firstly increased and then gradually decreased. Correspondingly, the memory transistor M_{F} is firstly turned off, and then the memory transistor M_{F} is slightly turned on. Hereinafter, a program cycle with four time periods T₁˜T₄ will be taken as an example. It is noted that the number of the time periods in the program cycle may be increased or decreased according to the practical requirements.

Please refer to FIG. 4B. The time interval between the time point tₐ and the time point t_{b} is the time period T₁. At the time point tₐ, the control signal S_{CL} is equal to an initial voltage V_{CLi}. Then, the control signal S_{CL} is gradually decreased from the initial voltage V_{CLi}. In other words, in the time period T₁, the control signal S_{CL} starts to be decreased from the initial voltage V_{CLi}.

The time interval between the time point t_{b} and the time point t_{c} is the time period T₂. At the time point t_{b}, the control signal S_{CL} is equal to the initial voltage V_{CLi} plus one voltage increment ΔV₂. Then, the control signal S_{CL} is gradually decreased from the voltage (V_{CLi}+ΔV₂). In other words, in the time period T₂, the control signal S_{CL} starts to be decreased from the voltage (V_{CLi}+ΔV₂). The voltage increment ΔV₂ is greater than zero.

The time interval between the time point t_{c} and the time point tₐ is the time period T₃. At the time point t_{c}, the control signal S_{CL} is equal to the initial voltage V_{CLi} plus two times the voltage increment ΔV₂. Then, the control signal S_{CL} is gradually decreased from the voltage (V_{CLi}+2ΔV₂). In other words, in the time period T₃, the control signal S_{CL} starts to be decreased from the voltage (V_{CLi}+2ΔV₂).

The time interval between the time point tₐ and the time point to is the time period T₄. At the time point t_{d}, the control signal S_{CL} is equal to the initial voltage V_{CLi} plus three times the voltage increment ΔV₂. Then, the control signal S_{CL} is gradually decreased from the voltage (V_{CLi}+3ΔV₂). In other words, in the time period T₄, the control signal S_{CL} starts to be decreased from the voltage (V_{CLi}+3ΔV₂).

FIG. 4C is a schematic timing diagram illustrating the change of a gate-source voltage V_{GS} of the memory transistor M_{F} in the non-volatile memory cell according to the third embodiment of the present invention. FIG. 4D is a schematic timing diagram illustrating the change of a source-drain voltage V_{SD} of the memory transistor M_{F} in the non-volatile memory cell according to the third embodiment of the present invention. For example, in the first storage state, no electrons are stored in the charge trapping layer of the memory transistor M_{F}. Under this circumstance, the threshold voltage Vt is −0.4V.

In the beginning of the time period T₁ (i.e., at the time point tₐ), the control signal S_{CL} is 6V. The gate-source voltage V_{GS} of the memory transistor M_{F} may be calculated according to the formula: V_{CLi}−V_{PP}=6V−6V=0V. Under this circumstance, the threshold voltage Vt of the memory transistor M_{F} is lower than the gate-source voltage V_{GS} of the memory transistor M_{F}. Consequently, the memory transistor M_{F} is turned off. Under this circumstance, the voltage at the node d is equal to the ground voltage (0V). That is, the source-drain voltage V_{SD} of the memory transistor M_{F} is 6V.

After the time point tₐ, the control signal S_{CL} is gradually continuously decreased. At the time point tₐ₁, the gate-source voltage V_{GS} of the memory transistor M_{F} is equal to the threshold voltage Vt of the memory transistor M_{F}. Under this circumstance, the memory transistor M_{F} is ready to be turned on, and the channel current I_{CH} is equal to zero.

In the time interval between the time point tₐ₁ and the time point tₐ₂, the gate-source voltage V_{GS} of the memory transistor M_{F} is lower than the threshold voltage Vt of the memory transistor M_{F}. Consequently, the memory transistor M_{F} is slightly turned on, and the channel current I_{CH} is generated. Meanwhile, since the CHHIHEI effect is generated, the gate current I_{G} corresponding to the hot electrons is larger. Consequently, a greater number of hot electrons are injected into the charge trapping layer of the memory transistor M_{F}.

In the time interval between the time point tₐ₁ and time point tₐ₂, the threshold voltage Vt of the memory transistor M_{F} is correspondingly increased with the increasing number of the hot electrons injected into the charge trapping layer. In addition, control signal SCS is gradually continuously decreased. Consequently, the difference between the gate-source voltage V_{GS} of the memory transistor M_{F} and the threshold voltage Vt of the memory transistor M_{F} is gradually increased. Under this circumstance, the channel current I_{CH} is gradually increased, but the magnitude of the channel current I_{CH} is lower than the magnitude of the magnitude of the limited current I_{LIM}. That is, the magnitude of the channel current I_{CH} is lower than 20 μA.

In the time interval between the time point tₐ₂ and the time point tₐ₃, the magnitude of the channel current I_{CH} reaches 20 μA. That is, the magnitude of the channel current is equal to the magnitude of the limited current I_{LIM}. Since the channel current I_{CH} is unable to be increased and the difference between the gate-source voltage V_{GS} of the memory transistor M_{F} and the threshold voltage Vt of the memory transistor M_{F} is gradually increased, the voltage at the node d is increased. That is, the source-drain voltage V_{SD} of the memory transistor M_{F} is decreased. Under this circumstance, the source-drain voltage V_{SD} of the memory transistor M_{F} is still higher than 3.5V. Consequently, the CHEI effect is continuously generated, and hot electrons are injected into the charge trapping layer of the memory transistor M_{F}.

In the time interval between the time point tₐ₃ and the time point t_{b}, the difference between the gate-source voltage V_{GS} of the memory transistor M_{F} and the threshold voltage Vt is gradually increased. Consequently, the source-drain voltage V_{SD} of the memory transistor M_{F} is gradually continuously decreased. In addition, after the time point tab, the source-drain voltage V_{SD} of the memory transistor M_{F} is lower than 3.5V. Meanwhile, the CHHIHEI effect cannot be generated. Consequently, the hot electrons are no longer injected into the charge trapping layer of the memory transistor M_{F}, and the threshold voltage Vt is not changed.

In the beginning of the time period T₂ (i.e., at the time point t_{b}), the control signal S_{CL} is increased to (V_{CLi}+ΔV₂). Under this circumstance, the threshold voltage Vt of the memory transistor M_{F} is lower than the gate-source voltage V_{GS} of the memory transistor M_{F}. Consequently, the memory transistor M_{F} is turned off. Under this circumstance, the voltage at the node d is equal to the ground voltage (0V). That is, the source-drain voltage V_{SD} of the memory transistor M_{F} is 6V.

After the time point t_{b}, the control signal S_{CL} is decreased. At the time point t_{b1}, the gate-source voltage V_{GS} of the memory transistor M_{F} is equal to the threshold voltage Vt of the memory transistor M_{F}. Meanwhile, the memory transistor M_{F} is ready to be turned on, and the channel current I_{CH} is zero.

In the time interval between the time point t_{b1} and the time point t_{b2}, the gate-source voltage V_{GS} of the memory transistor M_{F} is lower than the threshold voltage Vt of the memory transistor M_{F}. Consequently, the memory transistor M_{F} is slightly turned on, and the channel current I_{CH} is generated. Meanwhile, since the CHHIHEI effect is generated, the gate current I_{G} corresponding to the hot electrons is larger. Consequently, a greater number of hot electrons are injected into the charge trapping layer of the memory transistor M_{F}.

In the time interval between the time point t_{b1} and time point t_{b2}, the threshold voltage Vt of the memory transistor M_{F} is correspondingly increased with the increasing number of the hot electrons injected into the charge trapping layer. In addition, control signal SCS is gradually continuously decreased. Consequently, the difference between the gate-source voltage V_{GS} of the memory transistor M_{F} and the threshold voltage Vt of the memory transistor M_{F} is gradually increased. Under this circumstance, the channel current I_{CH} is gradually increased, but the magnitude of the channel current I_{CH} is lower than the magnitude of the magnitude of the limited current I_{LIM}. That is, the magnitude of the channel current I_{CH} is lower than 20 μA.

In the time interval between the time point t_{b2} and the time point t_{b3}, the magnitude of the channel current I_{CH} reaches 20 μA. That is, the magnitude of the channel current is equal to the magnitude of the limited current I_{LIM}. Since the channel current I_{CH} is unable to be increased and the difference between the gate-source voltage V_{GS} of the memory transistor M_{F} and the threshold voltage Vt of the memory transistor M_{F} is gradually increased, the voltage at the node d is increased. That is, the source-drain voltage V_{SD} of the memory transistor M_{F} is decreased. Under this circumstance, the source-drain voltage V_{SD} of the memory transistor M_{F} is still higher than 3.5V. Consequently, the CHHIHEI effect is continuously generated, and hot electrons are injected into the charge trapping layer of the memory transistor M_{F}.

In the time interval between the time point t_{b3} and the time point t_{b}, the difference between the gate-source voltage V_{GS} of the memory transistor M_{F} and the threshold voltage Vt is gradually increased. Consequently, the source-drain voltage V_{SD} of the memory transistor M_{F} is gradually continuously decreased. In addition, the source-drain voltage V_{SD} of the memory transistor M_{F} is lower than 3.5V. Meanwhile, the CHHIHEI effect cannot be generated. Consequently, the hot electrons are no longer injected into the charge trapping layer of the memory transistor M_{F}, and the threshold voltage Vt is not changed.

Similarly, in the beginning of the time period T₃ (i.e., at the time point tₐ), the control signal S_{CL} is increased to (V_{CLi}+A2V₂). Under this circumstance, the memory transistor M_{F} is turned off, and the source-drain voltage V_{SD} of the memory transistor M_{F} is 6V.

In the time interval between the time point t_{c1} and the time point tot, the memory transistor M_{F} is slightly turned on, and the channel current I_{CH} is generated. In addition, the magnitude of the channel current I_{CH} is lower than the limited current I_{LIM}. Meanwhile, since the CHHIHEI effect is generated, the gate current I_{G} corresponding to the hot electrons is larger. Consequently, a greater number of hot electrons are injected into the charge trapping layer of the memory transistor M_{F}.

In the time interval between the time point t_{c2} and the time point t_{c3}, the magnitude of the channel current I_{CH} reaches the limited current I_{LIM}. The source-drain voltage V_{SD} of the memory transistor M_{F} is decreased. The CHHIHEI effect is continuously generated. In addition, hot electrons are injected into the charge trapping layer of the memory transistor M_{F}.

In the time interval between the time point t_{c3} and the time point t_{d}, the magnitude of the channel current I_{CH} reaches the limited current I_{LIM}. The source-drain voltage V_{SD} of the memory transistor M_{F} is gradually continuously decreased to be lower than 3.5V. Meanwhile, the CHHIHEI effect cannot be generated. Consequently, the hot electrons are no longer injected into the charge trapping layer of the memory transistor M_{F}, and the threshold voltage Vt is not changed.

Similarly, in the time interval between the time point to and the time point tₐ₁ of the time period T₄, the memory transistor M_{F} is turned off. In addition, the source-drain voltage V_{SD} of the memory transistor M_{F} is 6V.

In the time interval between the time point tₐ₁ and the time point t_{d3}, the CHHIHEI effect is generated. Consequently, hot electrons are injected into the charge trapping layer of the memory transistor M_{F}.

In the time interval between the time point t_{d3} and the time point tₑ, the magnitude of the channel current I_{CH} reaches the limited current I_{LIM}. The source-drain voltage V_{SD} of the memory transistor M_{F} is gradually continuously decreased to be lower than 3.5V. Meanwhile, the CHHIHEI effect cannot be generated. Consequently, the hot electrons are no longer injected into the charge trapping layer of the memory transistor M_{F}, and the threshold voltage Vt is not changed.

As can be seen from the above descriptions of FIGS. 4A to 4D, the CHHIHEI effect is generated in each of the time periods T₁˜T₄. Since hot electrons are injected into the charge trapping layer of the memory transistor M_{F}, the program efficiency can be maintained. Moreover, the channel current I_{CH} of the memory transistor M_{F} is limited to the current value lower than 20 μA. Consequently, the power consumption during the program action can be effectively reduced.

Moreover, as shown in FIG. 4B, the lengths of the time periods T₁ T₄ are equal. In addition, the average falling rates of the control signal S_{CL} in the time periods T₁ T₄ are identical. It is noted that numerous modifications and alterations may be made while retaining the teachings of the invention. For example, in another embodiment, the lengths of different time periods are different. Alternatively, the average falling rates of the control signal in different time periods are different. For example, the control signal S_{CL} is decreased at a first average falling rate in the time period T₁, and the control signal S_{CL} is decreased at a second average falling rate in the time period T₂, wherein the first average falling rate is higher than the second average falling rate.

As shown in FIG. 4B, the control signal S_{CL} is increased by a voltage increment ΔV₂ at the start point of each of the time periods T₁˜T₄. For example, the control signal S_{CL} is equal to an initial voltage V_{CLi} at the time point tₐ, the control signal S_{CL} is equal to (V_{CLi}+ΔV₂) at the time point t_{b}, the control signal S_{CL} is equal to (V_{CLi}+2ΔV₂) at the time point t_{c}, and the control signal S_{CL} is equal to (V_{CLi}+3ΔV₂) at the time point t_{d}. In some other embodiments, the voltage increments of the control signal S_{CL} at different start points of the time periods T₁˜T₄ are different.

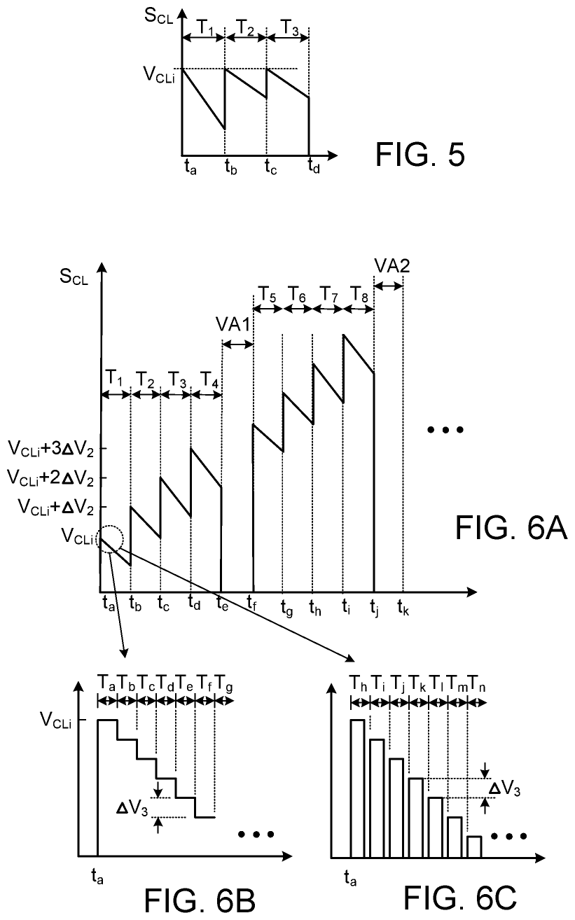

As shown in FIG. 5, it shows another example of the schematic timing diagram illustrating a waveform of a control signal S_{CL} when a program action is performed on the non-volatile memory cell. In this example, the control signal S_{CL} is fixed at an initial voltage V_{CLi} at the start point of each of the time periods T₁˜T₃. The maximum initial voltage V_{CLi} of the control signal S_{CL} can be determined according to the safe operation area (SOA) criteria of the memory transistor M_{F}. In other words, the voltage increment ΔV₂ at the start point of each of the time periods T₁˜T₃ is equal to zero. Moreover, falling rates of the control signal S_{CL} in the time periods T₁˜T₃ maybe different. For example, the control signal S_{CL} is decreased at a first average falling rate in the time period T₁, the control signal S_{CL} is decreased at a second average falling rate in the time period T₂ and in the time period T₃. The first average falling rate is higher than the second average falling rate.

In an embodiment, the present invention further provides a method of verifying the non-volatile memory cell. For example, in the program cycle, a verification action is performed on the non-volatile memory cell after several time periods. FIG. 6A is a schematic timing diagram illustrating a waveform of a control signal S_{CL} when a program action and a verification action are performed. For example, after the time periods T₁˜T₄ (e.g., at the time point tₑ), a verification action VA1 is performed on the non-volatile memory cell. When the verification action VA1 is performed, the non-volatile memory cell is read. Moreover, a control circuit (not shown) judges whether the storage state of the non-volatile memory cell is changed from the first storage state to the second storage state.

If the result of the verification action VA1 indicates that the non-volatile memory cell is in the first storage state, it means that the program action needs to be performed again. Consequently, in the next time periods T₅˜T₈ (i.e., from the time point t_{f} to the time point tⱼ), the control signal S_{CL} is continuously provided to the non-volatile memory cell.

After the time periods T₅˜T₈ (e.g., at the time point ti), another verification action VA2 is performed on the non-volatile memory cell. If the result of the verification action VA2 indicates that the non-volatile memory cell is in the second storage state, it means that the program action is completed. Whereas, if the result of the verification action VA2 indicates that the non-volatile memory cell is in the first storage state, it means that the program action needs to be performed again.

In the embodiment of FIG. 4B, the control signal S_{CL} is decreased at a constant falling rate in each time period. It is noted that the examples of decreasing the control signal S_{CL} are not restricted. FIGS. 6B and 6C are schematic timing diagrams illustrating two variant examples of decreasing the control signal S_{CL} in a time period.

As shown in FIG. 6B, the time interval T₁ is divided into plural sub-periods Tₐ˜T_{g}. The control signal S_{CL} contains plural pulses. Each of the plural pulses has a duty cycle of 100%. Moreover, each pulse has a corresponding pulse height. The pulse height of the first pulse is equal to the initial voltage V_{CLi}. After the first pulse, the pulse height of each pulse is smaller than the pulse height of the previous pulse. For example, the difference between the pulse heights of every two consecutive pulses is equal to a voltage decrement ΔV₃. In some other embodiments, the difference between the pulse heights of every two consecutive pulses is not restricted to the voltage decrement ΔV₃.

As shown in FIG. 6C, the time interval T₁ is divided into plural sub-periods Tₕ˜Tₙ. The control signal S_{CL} contains plural pulses. Each of the plural pulses has a duty cycle lower than 100%. For example, the duty cycle of each pulse is 75%. Moreover, each pulse has a corresponding pulse height. The pulse height of the first pulse is equal to the initial voltage V_{CLi}. After the first pulse, the pulse height of each pulse is smaller than the pulse height of the previous pulse. For example, the difference between the pulse heights of every two consecutive pulses is equal to a voltage decrement ΔV₃. In some other embodiments, the difference between the pulse heights of every two consecutive pulses is not restricted to the voltage decrement ΔV₃.

In FIGS. 6B and 6C, the lengths of the sub-periods Tₐ˜T_{g} are equal, and the lengths of the sub-periods Tₕ˜Tₙ are equal. In some other embodiments, the lengths of the sub-periods are not equal.

From the above descriptions, the present invention provides a programming method of a non-volatile memory cell. When a program action is performed, the upper limit of the channel current I_{CH} of the non-volatile memory cell is controlled to be lower than or equal to a limited current I_{LIM}. Furthermore, the control signal is adjusted during the program action. Consequently, the memory transistor of the non-volatile memory cell is selectively operated in an off state or a slightly-turned-on state. In this way, hot electrons can be injected into the charge trapping layer of the memory transistor, and the storage state of the non-volatile memory cell is changed from a first storage state to a second storage state.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A programming method of a non-volatile memory cell, the non-volatile memory cell comprising a memory transistor, the programming method comprising steps of:
limiting a channel current of the memory transistor lower than or equal to a limited current; and
providing a program voltage to a source terminal of the memory transistor, and providing a control signal to a gate terminal of the memory transistor,
wherein during a program cycle, a program action is performed, and the program cycle contains plural time periods,
wherein in a first time period of the plural time periods, the control signal is gradually decreased from a first voltage value, so that the memory transistor is firstly turned off and then turned on, wherein when the memory transistor is turned on, plural hot electrons are injected into the memory transistor,
wherein in a second time period of the plural time periods after the first time period, the control signal is gradually decreased from a second voltage value, so that the memory transistor is firstly turned off and then turned on, wherein when the memory transistor is turned on, the plural hot electrons are injected into the memory transistor, wherein the second voltage value is equal to the first voltage value plus a first voltage increment.

2. The programming method as claimed in claim 1, wherein the non-volatile memory cell further comprises a select transistor, wherein a source terminal of the select transistor is connected with a source line, a gate terminal of the select transistor is connected with a word line, a drain terminal of the select transistor is connected with the source terminal of the memory transistor, the gate terminal of the memory transistor is connected with a control line, and a current limiter is connected between the drain terminal of the memory transistor and a bit line for limiting the channel current lower than or equal to the limited current, wherein when the program action is performed, the source line receives the program voltage, the word line receives an on voltage, the control line receives the control signal, and the bit line receives a ground voltage.

3. The programming method as claimed in claim 1, wherein the first voltage increment is greater than or equal to zero, the second voltage value is higher than the first voltage value, or the second voltage value is equal to the first voltage value.

4. The programming method as claimed in claim 1, wherein the current limiter is a current source, and the current source provides the limited current.

5. The programming method as claimed in claim 1, wherein the control signal is decreased from the first voltage value at a first average falling rate in the first time period, and the control signal is decreased from the second voltage value at a second average falling rate in the second time period, wherein the first average falling rate is higher than or equal to the second average falling rate.

6. The programming method as claimed in claim 1, wherein in a third time period after the second time period of the plural time periods, the control signal is gradually decreased from a third voltage value, so that the memory transistor is firstly turned off and then turned on, wherein when the memory transistor is turned on, a channel hot hole induced hot electron injection effect is generated, and the plural hot electrons are injected into a charge trapping layer of the memory transistor, wherein the third voltage value is equal to the second voltage value plus a second voltage increment.

7. The programming method as claimed in claim 6, wherein the first voltage increment is equal to the second voltage increment.

8. The programming method as claimed in claim 6, wherein after the plural time periods, a verification action is performed to judge whether a storage state of the non-volatile memory cell is changed from a first storage state to a second storage state.

9. The programming method as claimed in claim 1, wherein in the first time period, the control signal contains plural pulses, wherein each pulse has a pulse height, and the pulse height of each pulse is lower than the pulse height of the previous pulse, wherein the pulse height of a first pulse of the plural pulses is equal to the first voltage value.

10. The programming method as claimed in claim 9, wherein a duty cycle of each pulse is 100%.

11. The programming method as claimed in claim 9, wherein a duty cycle of each pulse is smaller than 100%.

12. The programming method as claimed in claim 1, wherein the memory transistor is P-type transistor.

13. The programming method as claimed in claim 1, wherein the non-volatile memory cell further comprises a select transistor; wherein a source terminal of the select transistor is connected with a source line, a gate terminal of the select transistor is connected with a word line, a drain terminal of the select transistor is connected with the source terminal of the memory transistor, the gate terminal of the memory transistor is connected with a control line; wherein when the program action is performed, the source line receives the program voltage, the word line receives an on voltage, the control line receives the control signal, and the bit line receives a ground voltage; and, wherein the on voltage is capable of limiting a conductivity capability of the select transistor to determine the limited current.
